(19) United States
(12) Patent Application Publication
(10) Pub. No.: US 2025/0089396 A1
(43) Pub. Date: Mar. 13, 2025

(54) ELECTRONIC DEVICE

(71) Applicant: STMicroelectronics International N.V., Geneva (CH)

(72) Inventor: Arthur ARNAUD, La Tronche (FR)

(73) Assignee: STMicroelectronics International N.V., Geneva (CH)

(21) Appl. No.: 18/825,429

(22) Filed: Sep. 5, 2024

(30) Foreign Application Priority Data
Sep. 8, 2023 (FR) 2309484

(51) Int. Cl. H01L 31/0352; H01L 31/028; H01L 31/109; H04N 25/77

(52) U.S. Cl. CPC H10F 77/1433; H04N 25/77; H10F 30/222; H10F 77/122

(57) ABSTRACT

A pixel includes a first doped region of a first conductivity type and a second doped region of a second conductivity type. The first doped region includes first and second layers forming a heterojunction. A dopant concentration of the first layer is greater than a dopant concentration of the second layer. The first layer is made of a semiconductor material and the second layer includes quantum dots. The second doped region is in contact with the second layer, with the first layer being laterally surrounded by an insulated conductive wall that is biased to a negative voltage.

### PRIORITY CLAIM

This application claims the priority benefit of French Application for Patent No. 2309484, filed on Sep. 8, 2023, the content of which is hereby incorporated by reference in its entirety to the maximum extent allowable by law.

### TECHNICAL FIELD

The present disclosure generally concerns electronic devices and, in particular, optoelectronic devices comprising photodiodes.

### BACKGROUND

A photodiode is a semiconductor component having the ability to capture a radiation of the optical field and to turn it into an electric signal.

In a common type of photodiodes, the space charge area is located in a semiconductor material, generally silicon. However, silicon is little reactive to near infrared (NIR) and short-wave infrared (SWIR) wavelengths.

### SUMMARY

An embodiment provides a device comprising a pixel, the pixel comprising a first doped region of a first conductivity type and a second doped region of a second conductivity type, the first doped region comprising first and second layers forming a heterojunction, the first layer being made of a semiconductor material and the second layer comprising quantum dots, the second doped region being in contact with the second layer, the first layer being laterally surrounded with an insulated conductive wall, the dopant concentration of the first layer being greater than that of the second layer.

Another embodiment provides a method of controlling a device comprising a pixel, the pixel comprising a first doped region of a first conductivity type and a second doped region of a second conductivity type, the first doped region comprising first and second layers forming a heterojunction, the first layer being made of a semiconductor material and the second layer comprising quantum dots, the second doped region being in contact with the second layer, the first layer being laterally surrounded by an insulated conductive wall, the dopant concentration of the first layer being greater than that of the second layer, the method comprising the biasing of the insulated conductive wall to a negative voltage.

According to an embodiment, the first conductivity type is type N and the second conductivity type is type P.

According to an embodiment, the first layer is flush with a first surface of a semiconductor substrate, an interconnection network covering a second surface of the semiconductor substrate.

According to an embodiment, the interface between the first layer and the second layer is treated so as to allow the passing of charges.

According to an embodiment, the second doped region covers the second layer, the second layer separating the first layer and the second doped region.

According to an embodiment, the pixel comprises at least two first layers, the interface between each first layer and the second layer being surrounded by a third conductive layer.

According to an embodiment, each third conductive layer is separated from the corresponding first layer by a fourth insulating layer comprising an opening at each interface.

According to an embodiment, le pixel comprises four first layers, each first layer being surrounded by the insulated conductive wall.

According to an embodiment, the method comprises a repetition of a cycle of steps, the cycle comprising as many steps as first layers in the pixel, in each step, one of the third layers being biased with a first voltage, the other third layers being biased to a zero voltage, the third biased layer being different at each step of a cycle.

According to an embodiment, the first voltage is a negative voltage.

According to an embodiment, the second doped region laterally surrounds the first layer.

According to an embodiment, the second doped region is between the first layer and the insulated conductive wall.

According to an embodiment, the device comprises two pixels having a second doped region and a second layer in common, the second doped region being located between the insulated conductive walls surrounding the first layers of the two pixels.

An embodiment provides a time-of-flight measurement device comprising the device such as previously described.

### BRIEF DESCRIPTION OF THE DRAWINGS

The foregoing features and advantages, as well as others, will be described in detail in the rest of the disclosure of specific embodiments given by way of illustration and not limitation with reference to the accompanying drawings, in which:

FIG. 1 shows an embodiment of a pixel;

FIG. 2 illustrates the operation of the pixel of FIG. 1;

FIG. 3 shows another embodiment of a pixel;

FIG. 4 illustrates the operation of the pixel of FIG. 3;

FIG. 5 shows another embodiment of a pixel;

FIG. 6 shows a cross-section view of another embodiment of a pixel;

FIG. 7 shows a cross-section view along a plane A-A of the pixel of FIG. 6;

FIG. 8 shows a cross-section view according to a plane B-B of the pixel of FIG. 6; and

FIGS. 9A-9B illustrate the operation of the pixel of FIGS. 6, 7 and 8.

### DETAILED DESCRIPTION

Like features have been designated by like references in the various figures. In particular, the structural and/or functional features that are common among the various embodiments may have the same references and may dispose identical structural, dimensional and material properties.

For the sake of clarity, only the steps and elements that are useful for the understanding of the described embodiments have been illustrated and described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, when reference is made to terms qualifying absolute positions, such as terms “edge”, “back”, “top”, “bottom”, “left”, “right”, etc., or relative positions, such as terms “above”, “under”, “upper”, “lower”, etc., or to terms qualifying directions, such as terms “horizontal”, “vertical”, etc., it is referred, unless specified otherwise, to the orientation of the drawings.

Unless specified otherwise, the expressions “about”, “approximately”, “substantially”, and “in the order of” signify plus or minus 10%, preferably of plus or minus 5%.

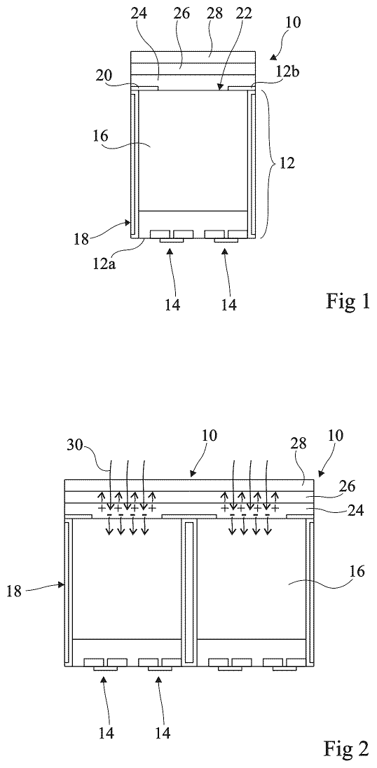

FIG. 1 shows an embodiment of a pixel 10 of an optoelectronic device. The device is a sensor, for example a time-of-flight sensor. The device comprises at least one pixel, for example at least one hundred pixels, for example at least one thousand pixels.

Pixel 10 is located inside and on top of a substrate 12. Substrate 12 is made of a semiconductor material, for example of silicon. Substrate 12 comprises a first surface 12a, or lower surface, and a second surface 12b, or upper surface, opposite to the first surface 12a. Electronic components are located inside and on top of substrate 12 on the side of the first surface 12a. Thus, transistors 14 are shown in FIG. 1. Transistors 14 are each represented by a source region and a drain region flush with surface 12a and a gate located on surface 12a. An interconnection network, which is not shown and comprises a stack of insulating layers comprising conductive tracks and conductive vias to allow electric connections, is for example located on surface 12a of the substrate.

Pixel 10 comprises a photodiode. The photodiode comprises a region 16 of the substrate. More precisely, region 16 corresponds to a doped well of substrate 12. Well 16 is located on the side of surface 12b. Preferably, well 16 is flush with surface 12b of substrate 12. Well 16 is made of a semiconductor material, for example made of the same material as substrate 12, for example of silicon. Well 16 is N-type doped and forms a portion of the cathode of the photodiode.

Well 16 is for example made of a single material, for example it is homogeneous. The dopant concentration in well 16 is for example substantially equal to 10¹⁶ dopants per cm³.

The pixel comprises a wall 18. Wall 18 is conductive and insulated. In other words, wall 18 comprises a conductive core, for example made of metal, and an insulating outer sheath at least laterally surrounding the conductive core. Wall 18 laterally surrounds well 16. The lateral walls of well 16 are for example in contact with the lateral walls of the sheath of wall 18.

Wall 18 extends at least along the height of well 16. In other words, wall 18 extends at least along the lateral walls of well 16. Preferably, wall 18 extends along the entire height of substrate 12.

The electronic components located in the region of substrate 12 surrounded by wall 18 are for example components associated with the pixel, for example the components forming the pixel control circuit or components of the circuit for processing the information obtained by the pixel.

The conductive core of wall 18 is configured to receive a voltage. The core of wall 18 is for example coupled to a node of application of said voltage by conductive tracks and conductive vias of the interconnection network, not shown.

The pixel for example comprises an insulating layer 20. Layer 20 for example covers surface 12b. Layer 20 then comprises an opening 22 in front of well 16. Opening 22 is for example located only in front of well 16. Opening 22 preferably has horizontal dimensions smaller than the dimensions of the upper surface of well 16. Thus, a portion, preferably a central portion, of the upper surface of well 16 is not covered by layer 20. Preferably, a peripheral portion of the upper surface is covered by layer 20. Preferably, wall 18 is covered by layer 20. Opening 22 for example corresponds to the pixel illumination window.

Pixel 10 further comprises a layer 24. Layer 24 covers the upper surface of substrate 12. More precisely, layer 24 covers at least the portion of well 16 exposed by opening 22. Layer 24 preferably covers insulating layer 20. Layer 24 is preferably in contact with well 16, more precisely with the portion of the upper surface of the well exposed by opening 22.

Layer 24 forms another portion of the cathode of the pixel photodiode. Layer 24 comprises quantum dots of the same conductivity type as well 16, for example type N. Layer 24 forms the photosensitive layer of the photodiode.

A quantum dot or semiconductor nanoparticle is a structure with a nanoscopic material which generates electron-hole pairs in the presence of the incidence of photons on the nanoscopic material structure.

A quantum dot comprises a semiconductor core. A quantum dot may also comprise a shell, preferably made of a semiconductor material, surrounding the core to protect it and to passivate the core. A quantum dot further comprises ligands, organic aliphatic compounds, metal-organic or inorganic molecules which extend from the shell and passivate, protect, and functionalize the semiconductor surface.

The composition of a quantum dot may be selected from among the following materials. The core is, for example, made of a material from among the following materials or from among an alloy of the following materials: CdSe, CdS, CdTe, CdSeS, CdTeSe, AgS, ZnO, ZnS, ZnSe, CuInS, CuInSe, CuInGaS, CuInGaSe, PbS, PbSe, PbSeS, PbTe, InAsSb, InAs, InSb, InGaAs, InP, InGaP, InAIP, InGaAlP, InZnS, InZnSe, InZnSeS, HgTe, HgSe, HgSeTe, Ge, Si. The shell is, for example, made of a material from among the following materials or from among an alloy of the following materials: CdSe, CdS, CdTe, CdSeS, CdTeSe, AgS, ZnO, ZnS, ZnSe, CuInS, CuInSe, CuInGaS, CuInGaSe, PbS, PbSe, PbSeS, PbTe, InAsSb, InAs, InSb, InGaAs, InP, InGaP, InAIP, InGaAlP, InZnS, InZnSe, InZnSeS, HgTe, HgSe, HgSeTe, Ge, Si.

Preferably, all the dimensions of the core are smaller than 20 nm, for example in the range from 2 to 15 nm. In particular, the diameter of each quantum dot is preferably in the range from 2 to 15 nm. By diameter, there is meant the diameter of the smallest sphere inside of which the quantum dot can be inscribed.

It is possible to select a size and a dimension of quantum dots capable of absorbing, with a significant absorption, any wavelength in a wide wavelength range. For example, it is possible find a size and a dimension of the quantum dots having an operating wavelength greater than 300 nm, for example in the range from 300 nm to 3,000 nm, which includes the visible range, near infrared and short-wave infrared. For example, layer 24 comprises quantum dots made of lead sulfide, for example quantum dots having a radius smaller than 10 nm, to obtain an absorption peak linked to the quantum confinement in infrared, while authorizing the absorption of wavelengths in the visible range.

Layer 24 for example has a thickness in the range from 100 nm to 500 nm. Well 16 for example has a thickness in the range from 2 μm to 10 μm.

The doping of layer 24, for example in the range from 10¹⁵ dopants per cm³ to 10¹⁶ dopants per cm³, is lighter than the doping of well 16, that is, than the dopant concentration in well 16, to enable layer 24 to be fully depleted by layer 16 and the voltage applied to layer 28.

The interface between well 16 and layer 24 forms a heterojunction (i.e., an interface, typically planar, between two different semiconductors having unequal bandgaps). Preferably, the upper surface of well 16 is treated, for example before the forming of layer 24, to ensure the forming of the heterojunction. The upper surface of well 16 is, for example, treated with a self-assembled monolayer (SAM), for example made of Ch₃I or of one or a plurality of other halogenated compounds. The monolayer is, for example, replaced with a thin metal oxide layer, for example made of ZnO. The upper surface of well 16 is, for example, treated with a halogen treatment.

Pixel 10 further comprises a layer 26. Layer 26 is a hole extraction layer. Layer 26 is of the conductivity type opposite to the conductivity type of well 16 and of layer 24, for example type P. Layer 26 is for example made of a P-type doped metal oxide or for example comprises quantum dots behaving as a P-type material due to the position of its Fermi level with respect to the Fermi level of the material of layer 24. Layer 26 corresponds to the anode of the photodiode. Layer 26 is transparent to the operating wavelengths of the pixel.

Layer 26 covers the upper surface of layer 24. Preferably, layer 26 covers at least the portion of layer 24 located in front of well 16. Layer 26 is preferably in contact with layer 24, for example at least with the portion of layer 24 located in front of well 16. The interface between layer 24 and layer 26 in front of well 16 correspond to a PN junction of the photodiode enabling to extract generated photocarriers which are not stored in well 16, the generated photocarriers being holes in the case of an N-doped well 16.

Pixel 10 further comprises a layer 28. Layer 28 is a conductive layer, for example made of metal oxide. Layer 28 is transparent to the operating wavelengths of the pixel. Layer 28 is for example made of sub-stoichiometric MoO₃, ITO, Va₂O₅, NiO, CuO, WO₃. Layer 28 forms part of the anode of the photodiode in the case where it is used to collect holes.

Layer 28 covers the upper surface of layer 26. Preferably, layer 28 covers at least the portion of layer 26 located in front of well 16. Layer 28 is preferably in contact with layer 26, for example at least with the portion of layer 26 located in front of well 16.

FIG. 2 illustrates the operation of the pixel 10 of FIG. 1. More precisely, FIG. 2 illustrates the operation of two pixels 10 of the device.

In the example of FIG. 2, adjacent pixels 10 have a common wall portion 18. Thus, the wells 16 of two neighboring pixels 10 are only separated by a wall 18. The cores of walls 18 are then biased to the same voltage. Alternatively, the walls 18 of two neighboring pixels may be separated from each other by a substrate region or an insulating region.

During the operation of the device, and during the operation of pixels 10, negative voltages are applied to the cores of walls 18 and to layer 28. The cores of walls 18 are preferably biased to a same voltage. The cores of walls 18 and layer 28 are for example biased to different negative voltages. For example, the cores of walls 18 are biased to a voltage in the range from −1 V to −3V. For example, layer 28 is biased to a voltage in the range from −2 V to −5 V.

When a light ray (represented by an arrow 30) reaches a pixel, the portion of the radiation having wavelengths within the operating wavelengths of the pixel cross layers 26 and 28. When said portion of the radiation reaches layer 24, the photons are absorbed in photosensitive layer 24. Pairs of electrons (−) and of holes (+) are thus generated in layer 24.

The negative voltage applied to the cores of walls 18 enables to deplete wells 16, which enables to attract electrons. The electrons are thus displaced and stored in well 16.

The negative voltage applied to layer 28 enables to attract the holes into hole extraction layer 28. The holes are thus extracted by layer 26.

The biasing of walls 18 further enables to limit the displacement of electrons from one well 16 to another and from a portion of layer 24 corresponding to a pixel to another portion of layer 24 corresponding to another pixel.

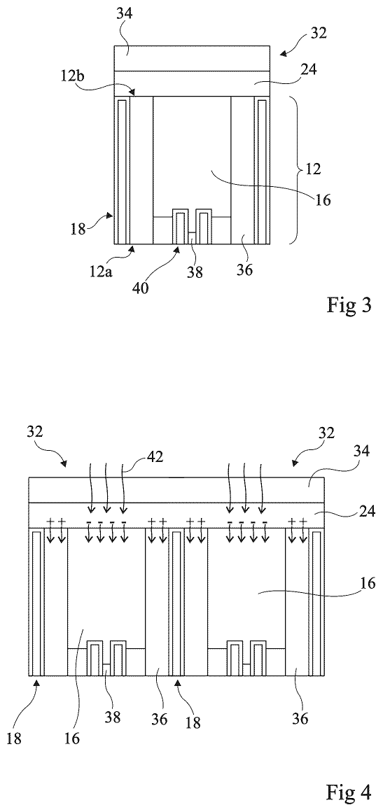

FIG. 3 shows another embodiment of a pixel 32 of an optoelectronic device. The device is a sensor, for example a time-of-flight sensor. The device comprises at least one pixel, for example at least one hundred pixels, for example at least one thousand pixels.

As in the pixel 10 of FIG. 1, pixel 32 is formed in substrate 12. Pixel 32 comprises well 16, wall 18, layer 24 and the interconnection network, not shown. Well 16 and layer 24 form a heterojunction, as in the pixel 10 of FIG. 1.

Pixel 32 differs from pixel 10 in that pixel 32 does not comprise layers 26 and 28. Pixel 32 comprises a layer 34. Layer 34 is an insulating layer, for example a passivation layer. Layer 34 is transparent to the operating wavelengths of the pixel. Layer 34 is for example made of Si₃N₄ or SiO₂. Layer 34 has no electric function.

Layer 34 covers the upper surface of layer 24. Preferably, layer 34 covers at least the portion of layer 24 located in front of well 16. Layer 34 is preferably in contact with layer 24, for example at least with the portion of layer 24 located in front of well 16.

Pixel 32 further comprises a well 36. Well 36 is located in substrate 12. Well 36 preferably laterally surrounds well 16. The upper surface of well 36 is flush with the upper surface of substrate 12 and is thus coplanar with the upper surface of well 16. Thus, the upper surface of well 16 is surrounded by the upper surface of well 36. Layer 24 is thus in contact with wells 16 and 36.

Well 36 extends for example at least along the height of well 16. Thus, well 36 extends preferably all along well 16. For example, well 36 extends along the entire height of substrate 12. Well 36 for example extends from surface 12a to surface 12b of substrate 12.

Well 36 is located between well 16 and wall 18. Preferably, well 36 is in lateral contact with wall 18, more precisely with the lateral walls of the insulating sheath of wall 18, and with the lateral walls of well 16. Well 16 is thus separated from wall 18 by, for example only by, well 36. In a device comprising more than one pixel 32, each well 16 is for example separated from the neighboring well 16 by two wells 36 and at least one wall 18, for example only two wells 36 and one wall 18.

Well 36 is for example made of the material of substrate 12, for example of silicon. Well 36 is doped with the conductivity type opposite to the conductivity type of well 16, for example type P. Well 36 forms the hole extraction region. The dopant concentration of well 36 is for example in the range from 10¹⁷ to 10¹⁸ dopants per cm³.

Pixel 32 for example comprises a region 38, in contact with well 16 and flush with surface 12a of the substrate. Region 38 is for example made of the same material as substrate 12, for example of silicon, for example doped with the same conductivity type as well 16. The dopant concentration of well 16 is lower than the dopant concentration of region 38. Region 38 is for example separated from the rest of substrate 12 by walls 40, for example insulated conductive walls. Region 38 for example enables to collect electrons. Region 38 is preferably coupled to the interconnection network, not shown.

FIG. 4 illustrates the operation of the pixel of FIG. 3. More precisely, FIG. 4 illustrates the operation of two pixels 32 of the device.

In the example of FIG. 4, the adjacent pixels 32 adjacent have a common portion of wall 18. Thus, the wells 16 of two neighboring pixels 32 are only separated by one wall 18 and two wells 36. The cores of walls 18 are then biased to the same voltage. Alternatively, the walls 18 of two neighboring pixels may be separated from each other by a substrate region or an insulating region.

During the operation of the device, and during the operation of pixels 32, negative voltages are applied to the cores of walls 18. The cores of walls 18 are preferably biased to a same negative voltage. For example, the cores of walls 18 are biased to a voltage in the range from −1 V to −3 V.

When a light ray (represented by an arrow 42) reaches a pixel, the portion of the radiation having wavelengths within the operating wavelengths of the pixel cross layer 34. When said portion of the radiation reaches layer 24, the photons are absorbed in photosensitive layer 24. Pairs of electrons and holes are thus generated in layer 24.

The negative voltage applied to the cores of walls 18 enables to deplete wells 16, which enables to attract electrons. The electrons are thus displaced and stored in well 16. The holes are extracted by well 36.

The biasing of walls 18 further enables to limit the displacement of electrons from one well 16 to another and from a portion of layer 24 corresponding to a pixel to another portion of layer 24 corresponding to another pixel.

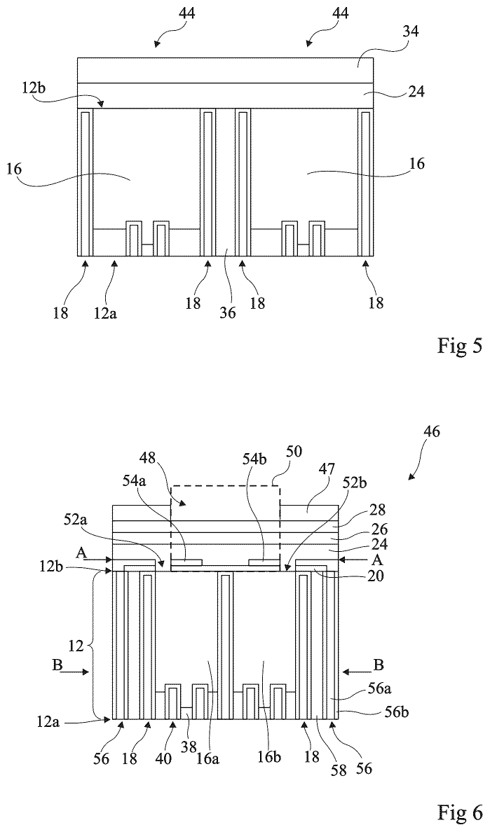

FIG. 5 shows another embodiment of pixels 44 of an optoelectronic device. The device is a sensor, for example a time-of-flight sensor. The device comprises at least two pixels, for example at least one hundred pixels, for example at least one thousand pixels.

As in the pixel 32 of FIG. 3, pixel 44 is formed in substrate 12. Pixel 44 comprises well 16, wall 18, layer 24, layer 34, well 36, and the interconnection network, not shown. Well 16 and layer 24 form a heterojunction, as in the pixel 32 of FIG. 3.

Pixels 44 differ from the pixel 32 of FIG. 3 in that well 36 is not located inside of the wall 18 of a pixel.

In the embodiment of FIG. 5, adjacent pixels do not comprise a common wall 18. In other words, the walls 18 of different pixels are separated from one another. More precisely, the walls 18 of two neighboring pixels 44 are separated from one another by well 36. Thus, the wells 16 of two neighboring pixels are separated by two portions of walls 18 and a well 36. Each wall 18 is for example surrounded by well 36. Well 36 is thus common to a plurality of pixels 44, for example to all pixels 44.

Well 36 is preferably in lateral contact with the sides of walls 18, that is, with the side walls of the insulating sheaths of walls 18. Well 36 extends preferably along the entire height of substrate 36, to be able to be coupled to the interconnection network, not shown. Further, an upper surface of well 36 is flush with surface 12b of the substrate and is thus coplanar with the upper surface of well 16. Layer 24 is thus in contact with the upper surfaces of wells 16 and 36.

The operation of the pixels 44 of FIG. 5 differs from the operation of the pixels 32 of FIG. 4 in that holes are extracted by the well 36 located outside of walls 18.

FIGS. 6 to 8 show an embodiment of pixels 46 of an optoelectronic device. The device is a sensor, for example a time-of-flight sensor. The device comprises at least one pixel, for example at least one hundred pixels, for example at least one thousand pixels.

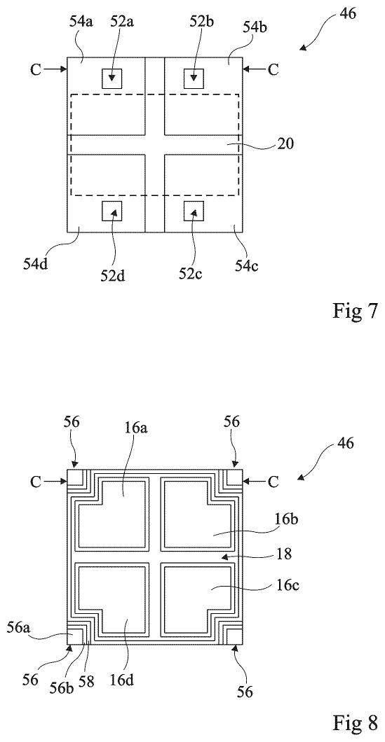

More precisely, FIG. 6 shows a cross-section view of pixel 46 along a plane C-C of FIGS. 7 and 8. FIG. 7 shows a cross-section view along a plane A-A of the pixel of FIG. 6. FIG. 8 shows a cross-section view along a plane B-B of the pixel of FIG. 6.

Pixel 46 comprises elements common to the pixel 10 of FIGS. 1 and 2. These elements will not be described again in detail. Thus, pixel 46, located in substrate 12, comprises layer 20, layer 24, layer 26, layer 28 and the interconnection network, not shown.

Further, pixel 46 comprises at least two wells 16. In the example of FIGS. 6, 7, 8, pixel 46 comprises four wells 16a, 16b, 16c, and 16d. The four wells are arranged in an array, that is, in two rows and in two columns. Each well 16a, 16b, 16c, and 16d for example comprises, as in FIG. 3, a region 38 surrounded by a wall 40.

As in FIGS. 1 and 2, wells 16a, 16b, 16c, and 16d are surrounded by a wall 18, comprising, as in FIGS. 1 and 2, a conductive core and an insulating sheath. Preferably, wells 16a, 16b, 16c, and 16d are surrounded by a same wall 18. Wall 18 thus extends between wells 16a, 16b, 16c, and 16d and around wells 16a, 16b, 16c, and 16d.

Layer 28 is for example covered with a layer 47. Layer 47 is preferably in contact with layer 28. Layer 47 comprises an opening 48. Opening 48 preferably extends at least partially in front of each well 16a, 16b, 16c, and 16d. Preferably, layer 47 extends in front of a portion of wells 16a, 16b, 16c, and 16d. Layer 47 is made of a material opaque to the operating wavelengths of pixel 46. Opening 48 thus defines the illumination window 50 of pixel 46, that is, the portion of layers 24, 26, 28 reached by light rays. The portion of layer 24 located in window 50, that is, located opposite opening 48, corresponds to the location of generation of the electron-hole pairs.

Layer 20 partially covers, as in the embodiments of FIGS. 1 and 2, wells 16a, 16b, 16c, and 16d. Preferably, layer 20 covers the portions of wells 16a, 16b, 16c, and 16d located in front of opening 48. Layer 20 further covers wall 18. Layer 20 comprises an opening 52a, 52b, 52c, 52d in front of each well 16a, 16b, 16c, and 16d. More precisely, opening 52a, respectively 52b, respectively 52c, respectively 52d, is located in front of well 16a, respectively 16b, respectively 16c, respectively 16d. Thus, the portions of wells 16a, 16b, 16c, and 16d exposed by openings 52a, 52b, 52c, 52d are coupled to, for example in contact with, layer 24. Openings 52a, 52b, 52c, 52d form the paths of the electrons flowing towards the wells.

Pixel 46 comprises, for each well 16a, 16b, 16c, and 16d, a conductive layer 54a, 54b, 54c, 54d. Layer 54a, respectively 54b, respectively 54c, respectively 54d surrounds opening 52a, respectively 52b, respectively 52c, respectively 52d. Each layer 54a, 54b, 54c, 54d rests on layer 20. Thus, the portions of layers 54a, 54b, 54c, 54d located in front of wells 16a, 16b, 16c, and 16d are separated from wells 16a, 16b, 16c, and 16d by layer 20. Layers 54a, 54b, 54c, 54d are for example in contact with layer 24. The different layers 54a, 54b, 54c, 54d are not in contact with one another.

Layers 54a, 54b, 54c, 54d are configured to be biased to control voltages, preferably different voltages. Thus, each layer 54a, 54b, 54c, 54d is for example coupled to the interconnection network, not shown, by an insulated conductive via 56. Pixel 46 thus comprises as many vias 56 as layers 54a, 54b, 54c, 54d, that is, four vias 56 in the embodiment of FIGS. 6 to 8. Each via 56 comprises a conductive core 56a and an insulating sheath 56b. The conductive core 56a of each via 56 is coupled, by one end to one of layers 54a, 54b, 54c, 54d and by another end to conductive vias or tracks of the interconnection network so as to be coupled to a source of application of a control voltage. Each via 56 thus preferably thoroughly crosses substrate 12, that is, extends from surface 12a to surface 12b. Each via 56 is for example separated from wall 18 by a portion 58 of substrate 12. Each via 56 is for example separated from the wells by a portion 58 and by wall 18.

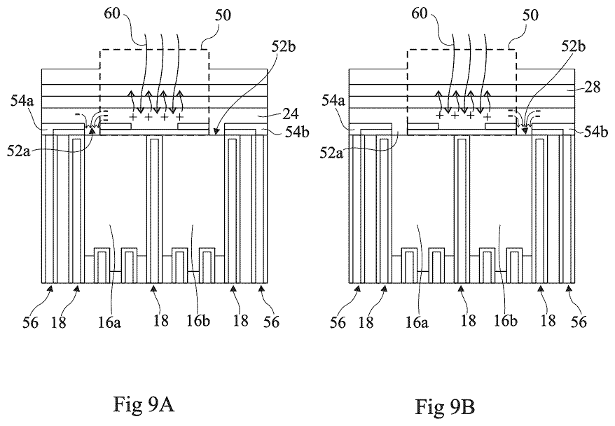

FIGS. 9A-9B illustrate the operation of the pixels 46 of FIGS. 6, 7, and 8, where FIG. 9A and FIG. 9B each show a step of the operation of pixel 46.

The operation of pixel 46 for example comprises as many steps as wells 16. Thus, the operation of the pixel 46 such as described in relation with FIGS. 6 to 8 comprises four steps. In FIGS. 9A-9B, only two of the four steps are shown. More precisely, FIG. 9A shows a step of storage in well 16a and FIG. 9B shows a step of storage in well 16b.

Pixel 46 is for example configured to perform a demodulation of the signal generated by the received light. For example, pixel 46 is present in a time-of-flight measurement device.

During the step of FIG. 9A of the operation of pixel 46, negative voltages are applied to the core of wall 18 and to layer 28. For example, the core of wall 18 is biased to a voltage in the range from −1 V to −3 V. For example, layer 28 is biased to a voltage in the range from −2 V to −5 V.

When a light ray (represented by an arrow 60) reaches a pixel 46, more precisely reaches window 50, the portion of the radiation having wavelengths within the operating wavelengths of the pixel cross layers 26 and 28. When said portion of the radiation reaches layer 24, the photons are absorbed in photosensitive layer 24. Pairs of electrons (−) and of holes (+) are thus generated in layer 24.

Layer 54a is biased to a negative voltage and layers 54b, 54c and 54d are biased to zero voltages. Said negative voltage is for example in the range from −1 V and −4V.

The negative voltage applied to the cores of walls 18 enables to deplete wells 16. The voltages of layers 54a, 54b, 54c, and 54d enable to ensure that a major part, for example more than 75%, of the generated electrons are thus displaced and stored in well 16a.

The negative voltage applied to layer 26 enables to attract the holes into hole extraction layer 26. The holes are thus extracted by layer 26.

The step of FIG. 9B is similar to the step of FIG. 9A. The step of FIG. 9B differs from the step of FIG. 9A in that the electrons are as a majority, for example at least by 75%, stored in well 16b. For this purpose, layer 54b is biased to a negative voltage and layers 54a, 54c, and 54d are biased to zero voltages. Said negative voltage is for example in the range from −1 V to −4 V.

In other words, pixel 46 comprises as many steps as wells 16 and comprises, for each step, the biasing of the layer 54 corresponding to one of the wells to a negative voltage and the biasing of the other layers 54 to a zero voltage, the core of wall 18 and layer 26 being biased to negative voltages.

During the operation of pixels 46, for example in a time-of-flight measurement device, the different steps are carried out in alternation, during preferably equal time periods. Thus, the operation of the pixels comprises the repeating of a cycle comprising the four steps preferably carried out for a same time period.

Various embodiments and variants have been described. Those skilled in the art will understand that certain features of these various embodiments and variants may be combined, and other variants will occur to those skilled in the art. For example, the embodiment of FIGS. 1 and 2 may comprise region 38 and walls 40.

Further, the charges (electrons and holes) may be exchanged. Thus, according to other embodiments, the conductivity types may be exchanged, layer 26 then being an electron extraction layer.

Finally, the practical implementation of the described embodiments and variants is within the abilities of those skilled in the art based on the functional indications given hereabove.

1. A device comprising a pixel, wherein the pixel comprises:
a first doped region of a first conductivity type;
a second doped region of a second conductivity type;
the first doped region comprising a first layer and a second layer forming a heterojunction;
wherein the first layer is made of a semiconductor material and the second layer comprises quantum dots;
wherein the second doped region is in contact with the second layer;
wherein the first layer is laterally surrounded by an insulated conductive wall; and
wherein a dopant concentration of the first layer is greater than a doping concentration of a second layer.

2. The device according to claim 1, wherein the first conductivity type is type N and the second conductivity type is type P.

3. The device according to claim 1, wherein the first layer is flush with a first surface of a semiconductor substrate.

4. The device according to claim 3, further comprising an interconnection network covering a second surface of the substrate.

5. The device according to claim 1, wherein an interface between the first layer and the second layer is treated so as to allow the passing of charges.

6. The device according to claim 1, wherein the second doped region covers the second layer, the second layer separating the first layer and the second doped region.

7. The device according to claim 6, wherein the pixel comprises at least two first layers, and wherein an interface between each first layer and the second layer is surrounded by a third conductive layer.

8. The device according to claim 7, wherein each third conductive layer is separated from the corresponding first layer by a fourth insulating layer comprising an opening at each interface.

9. The device according to claim 8, wherein the pixel comprises four first layers, each first layer being surrounded by the insulated conductive wall.

10. The device according to claim 9, configured for operation using a repetition of a cycle of steps, the cycle comprising as many steps as first layers in the pixel, and wherein at each step one of the third conductive layers is biased with a first voltage while the other third conductive layers are biased to a zero voltage, and wherein the third conductive layer that is biased with the first voltage is different at each step of the cycle.

11. The device according to claim 10, wherein the first voltage is a negative voltage.

12. The device according to claim 1, wherein the second doped region laterally surrounds the first layer.

13. The device according to claim 12, wherein the second doped region is located between the first layer and the insulated conductive wall.

14. The device according to claim 1, wherein the device comprises two pixels having a second region and a second layer in common, the second region being located between insulated conductive walls surrounding the first layers of the two pixels.

15. The device according to claim 1, configured for operation by biasing the insulated conductive wall to a bias voltage.

16. A time-of-flight measurement device, comprising the device according to claim 1.

17. A method of controlling a pixel which includes a first doped region of a first conductivity type and a second doped region of a second conductivity type, the first doped region comprising first and second layers forming a heterojunction, the first layer being made of a semiconductor material and the second layer comprising quantum dots, the second region doped being in contact with the second layer, the first layer being laterally surrounded by an insulated conductive wall, wherein a dopant concentration of the first layer is greater than a dopant concentration of the second layer, the method comprising:
biasing the insulated conductive wall to a negative voltage; and
generating pairs of electrons and holes in response to photons received in the second layer; and
storing the electrons in the first layer.

18. The method according to claim 17, wherein the second doped region covers the second layer, the second layer separating the first layer and the second doped region, and wherein the pixel comprises at least two first layers, the interface between each first layer and the second layer being surrounded by a third conductive layer, the method further comprising:
repeating a cycle of steps, the cycle comprising as many steps as first layers in the pixel;
wherein, at each step, one of the third conductive layers is biased with a first voltage and the other third conductive layers are biased to a zero voltage; and
wherein the third conductive layer that is biased with the first voltage is different at each step of the cycle.

19. The method according to claim 18, wherein the first voltage is a negative voltage.
